(19) United States
(12) Patent Application Publication
(10) Pub. No.: US 2004/0187909 A1
(43) Pub. Date: Sep. 30, 2004

(54) Solar cell unit and method for mounting the solar cell unit on roof

(75) Inventors: Hirotaka Sato, Kitakatsuragi-gun (JP); Kosuke Ueda, Ikoma-gun (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/812,032

(22) Filed: Mar. 30, 2004

(30) Foreign Application Priority Data
Mar. 31, 2003 (JP) 2003-096330

(51) Int. Cl. H01L 25/00

(52) U.S. Cl. 136/251; 136/244

(57) ABSTRACT

A solar cell unit includes a solar cell module, a module frame provided around the solar cell module as supporting the solar cell module for mounting the solar cell unit on an oblique roof, and a drain channel provided along an edge of the module frame outside the module frame.

### CROSS-REFERENCE TO RELATED APPLICATIONS

This application is related to Japanese patent application No. 2003-096330 filed on Mar. 31, 2003, whose priority is claimed under 35 USC § 119, the disclosure of which is incorporated by reference in its entirety.

### BACKGROUND OF THE INVENTION

1. Field of the Invention

The present invention relates to a solar cell unit and a method for mounting the solar cell unit on a roof. More specifically, the invention relates to the construction of a solar cell unit having a drain channel for draining rainwater when the unit is mounted on an oblique roof, and a method for mounting the solar cell unit on the roof.

2. Description of the Related Art

A conventional solar cell unit includes a solar cell module and an engagement piece projecting from a rear surface of a horizontal frame thereof located on the side of a roof ridge for engagement with a tiling lath for easy positioning thereof with respect to a roof surface (see, for example, Japanese Unexamined Patent Publication No. Hei 11-200561 (1999)).

In general, the solar cell unit is designed so as to be mounted on an oblique roof in place of roof tiles, and a plurality of such solar cell units are mounted in adjoining relation on an installation region provided by removing the roof tiles. A base surface of the roof is exposed in the installation region from which the roof tiles are removed. Therefore, if rainwater intrudes into gaps between the adjacent solar cell units and gaps between the solar cell units and roof tiles disposed adjacent the units, the base surface of the roof may be corroded.

A conceivable approach to this problem is to arrange the adjacent solar cell units in intimate contact with each other and arrange the solar cell units in intimate contact with the adjacent roof tiles without the gaps for prevention of the intrusion of the rainwater. However, the roof tiles have a greater dimensional tolerance than the solar cell units. Hence, there is a high possibility that the size of the installation region provided by removing the roof tiles significantly differs from the total size of the solar cell units arranged on the installation region.

Where the solar cell units are designed so as to be arranged in intimate contact with each other or with the roof tiles adjacent to the solar cell units, the significant dimensional difference between the size of the installation region and the total size of the solar cell units makes it difficult to install the solar cell units on the installation region. More specifically, if the size of the installation region is smaller than the total size of the solar cell units arranged on the installation region, the installation of the solar cell units is difficult. On the other hand, if the size of the installation region is greater than the total size of the solar cell units arranged on the installation region, wider gaps are defined between the solar cell units and edges of the roof tiles. Therefore, channel members or the like are provided separately from the units in the gaps for prevention of the intrusion of the rainwater.

### SUMMARY OF THE INVENTION

Therefore, the present invention is directed to a solar cell unit and a method for mounting the solar cell unit on a roof, which can solve at least one of the aforesaid problems.

It is an object of the present invention to provide a solar cell unit and a method for mounting the solar cell unit on an oblique roof, which ensure that, when a plurality of such solar cell units are mounted on the oblique roof, rainwater intruding into gaps defined between the adjacent solar cell units and gaps defined between the solar cell units and roof tiles disposed adjacent the units can be drained to be prevented from reaching a base surface of the roof.

It is another object of the present invention to provide a solar cell unit and a method for mounting the solar cell unit on an oblique roof, which ensure that a plurality of such solar cell units can easily be mounted on the oblique roof without an influence of a dimensional difference between the size of an installation region and the total size of the solar cell units arranged on the installation region.

According to the present invention, there is provided a solar cell unit, which comprises: a solar cell module; a module frame provided around the solar cell module as supporting the solar cell module for mounting the solar cell unit on an oblique roof; and a drain channel provided along an edge of the module frame outside the module frame.

That is, the drain channel is provided along the edge of the module frame outside the module frame in the inventive solar cell unit. When a plurality of such solar cell units are arranged on the oblique roof, rainwater intruding into gaps defined between the module frames can be received by the drain channels of the respective units and guided toward an eave of the oblique roof thereby to be drained. Therefore, the rainwater intruding into the gaps between the adjacent solar cell units does not reach a base surface of the roof, so that the corrosion of the base surface of the roof can be prevented.

Even if the gaps are provided between the solar cell units, the rainwater does not reach the base surface of the roof. Therefore, a dimensional difference between the size of the installation region of the oblique roof and the total size of the solar cell units arranged on the installation region can flexibly be accommodated by positively providing the gaps between the solar cell units and properly adjusting the width of the gaps when the solar cell units are mounted on the roof.

### BRIEF DESCRIPTION OF THE DRAWINGS

FIG. 1 is a perspective view schematically illustrating the overall construction of a solar cell unit according to an embodiment of the present invention;

FIG. 2 is a perspective view schematically illustrating a plurality of solar cell units of FIG. 1 mounted on an installation region of an oblique roof;

FIG. 3 is an explanatory diagram illustrating a portion A of FIG. 2 as seen parallel to a surface of the roof from the side of an eave;

FIG. 4 is an explanatory diagram illustrating a portion B of FIG. 2 as seen parallel to the surface of the roof from the side of the eave; and

FIG. 5 is an explanatory diagram illustrating a portion C of FIG. 2 as seen parallel to the surface of the roof from the side of the eave.

### DESCRIPTION OF THE PREFERRED EMBODIMENTS

A solar cell unit according to the present invention comprises: a solar cell module; a module frame provided around the solar cell module as supporting the solar cell module for mounting the solar cell unit on an oblique roof; and a drain channel provided along an edge of the module frame outside the module frame.

In the inventive solar cell unit, the solar cell module herein means a planar module including a plurality of solar cells arranged in a plane and electrically connected to one another.

In the inventive solar cell unit, the solar cell module may have a rectangular shape. The module frame may include two horizontal frame portions provided parallel to each other to be disposed on the side of a roof ridge and on the side of an eave, respectively, when the solar cell unit is mounted on the oblique roof, and a first side frame portion and a second side frame portion respectively extending from opposite ends of one of the horizontal frame portions to opposite ends of the other horizontal frame portion. The drain channel may be provided along an outer side of the first side frame portion. With this arrangement, where a plurality of such solar cell units are arranged parallel to the roof ridge or the eave on the oblique roof with the first side frame portion of one of two adjacent solar cell units and the second side frame portion of the other solar cell unit being disposed in opposed relation, rainwater intruding into a gap defined between the first side frame portion of the one unit and the second side frame portion of the other unit can be received by the drain channel provided along the first side frame portion of the one unit.

In the inventive solar cell unit, the drain channel may have a rib projecting upward from a bottom of the drain channel and extending longitudinally of the drain channel. With this arrangement, a flow channel of the rainwater flowing through the drain channel is restricted by the rib, so that the flow amount and flow rate of the rainwater can properly be maintained according to the amount of the rainwater flowing into the drain channel.

That is, where the amount of the rainwater is small, the rainwater introduced into the drain channel flows through the flow channel narrowly restricted by the rib, so that the flow rate is naturally increased. As a result, dust introduced together with the rainwater into the drain channel can be drained from the drain channel together with the rainwater. Thus, accumulation of the dust in the drain channel can be prevented.

On the other hand, where the amount of the rainwater is great, the rainwater introduced into the drain channel overflows the flow channel narrowly restricted by the rib, and the overflowing rainwater is drained through an adjacent flow channel separated from the first flow channel by the rib. The rib may include two or more ribs.

In the inventive solar cell unit, the drain channel may have a barrier plate which closes one end of the drain channel located on the side of the roof ridge. With this arrangement, where the rainwater flows back in a direction opposite from the inclination of the roof in the drain channel for a certain reason, for example, due to a strong wind blowing toward the roof ridge from the eave of the oblique roof, the rainwater thus flowing back can be blocked by the barrier plate. As a result, the rainwater flowing in the drain channel is prevented from being leaked from the ridge-side end of the drain channel from which the rainwater is not normally drained. Thus, the rainwater is prevented from wetting a base surface of the roof.

In the inventive solar cell unit, the drain channel may include a channel bottom and opposite side walls. The second side frame portion may have a planar projection projecting horizontally outward from the entire upper edge of the second side frame portion. The projection may be located at a higher level than the side walls of the drain channel. With this arrangement, where a plurality of such solar cell units are arranged parallel to the roof ridge or the eave on the oblique roof with the first side frame portion of one of two adjacent units and the second side frame portion of the other unit being disposed in opposed relation, the projection of the other unit overhangs the drain channel of the one unit. Thus, an unnecessarily great amount of rainwater is prevented from flowing into the drain channel through the gap defined between the first side frame portion and the second side frame portion.

In the inventive solar cell unit, the drain channel and the projection may each have a predetermined width. The width of the drain channel may be greater than the width of the projection. With this arrangement, where a plurality of such solar cell units are arranged parallel to the roof ridge or the eave on the oblique roof with the first side frame portion of one of two adjacent units and the second side frame portion of the other unit being disposed in opposed relation, the drain channel of the one unit is partly covered with the projection of the other unit, and the gap is defined between the first side frame portion of the one unit and the second side frame portion of the other unit. Thus, an unnecessarily great amount of rainwater is prevented from flowing into the drain channel through the gap defined between the first side frame portion and the second side frame portion, and a dimensional difference between the size of the installation region and the total size of the solar cell units can flexibly be accommodated by properly adjusting the width of the gap (clearance) when the solar cell units are mounted on the roof.

In the inventive solar cell unit, the projection may have a rib projecting downward from a rear surface of the projection and extending along the second side frame portion for dripping rainwater flowing along the rear surface of the projection. With this arrangement, the rainwater flowing from a front surface to a rear surface of the second side frame portion is blocked to be dripped downward by the rib. Thus, rainwater falling on the solar cell units is prevented from intruding into the rear side of the solar cell units from the front surface of the second side frame portion. Particularly where a plurality of such solar cell units are arranged parallel to the roof ridge or the eave on the oblique roof with the first side frame portion of one of two adjacent units and the second side frame portion of the other unit being disposed in opposed relation, the rainwater dripping along the rib is received by the drain channel of the solar cell unit thereby to be prevented from wetting the base surface of the roof.

In the inventive solar cell unit, the first side frame portion may further have an auxiliary drain channel projecting under the module and extending along an inner side of the first side frame portion. With this arrangement, rainwater intruding into the rear side of the solar cell unit for a certain reason can be received by the auxiliary drain channel.

In the inventive solar cell unit, the first side frame portion may further have a planar auxiliary projection projecting horizontally outward from the entire upper edge of the first side frame portion. With this arrangement, the auxiliary projection is located above the drain channel, so that an unnecessarily great amount of rainwater is prevented from flowing into the drain channel. Particularly where a plurality of such solar cell units are arranged parallel to the roof ridge or the eave on the oblique roof with the first side frame portion of one of two adjacent units and the second side frame portion of the other unit being disposed in opposed relation, the auxiliary projection of the one unit and the projection of the other unit are disposed in opposed spaced relation above the drain channel, thereby minimizing the amount of the rainwater flowing into the drain channel.

According to another aspect of the present invention, there is provided a method for mounting a plurality of solar cell units on an oblique roof, the solar cell units each comprising a rectangular solar cell module, a module frame having two horizontal frame portions and first and second side frame portions, and a drain channel provided along the first side frame portion as described above, the method comprising the step of mounting the solar cell units parallel to a roof ridge or an eave on the oblique roof so that the first side frame portion of one of two adjacent solar cell units and the second frame portion of the other solar cell unit are opposed to each other with a gap being defined therebetween and the drain channel provided along the first side frame portion of the one unit is located below the gap.

In this method, the gap is defined between the first side frame portion of the one unit and the second side frame portion of the other unit, and the drain channel is located below the gap. Therefore, rainwater intruding into the gap between the units is received by the drain channel thereby to be drained. As a result, the rainwater intruding into the gap between the units does not reach the base surface of the roof, so that the corrosion of the base surface of the roof can be prevented.

According to further another aspect of the present invention, there is provided a method for mounting a solar cell unit on a partly tile-covered oblique roof, the solar cell unit comprising a rectangular solar cell module, a module frame having two horizontal frame portions and first and second side frame portions, and a drain channel provided along the first side frame portion as described above, the method comprising the steps of: providing a rectangular installation region on the oblique roof, the rectangular installation region having two horizontal edges parallel to a roof ridge or an eave and two side edges respectively extending from opposite ends of one of the horizontal edges to opposite ends of the other horizontal edge; and mounting the unit on the installation region so that the first side frame portion of the unit is opposed to one of the side edges of the installation region to provide a gap between the first side frame portion and the one side edge and the drain channel provided along the first side frame portion is located below the gap; wherein the side edges of the installation region are each defined by a side edge of a roof tile; wherein the gap providing step comprises the step of providing the gap between the first side frame portion and the side edge of the roof tile.

In this method, the gap is defined between the first side frame portion of the solar cell unit and the side edge of the roof tile, and the drain channel is located below the gap. Therefore, rainwater intruding into the gap between the unit and the roof tile is received by the drain channel thereby to be drained. As a result, the rainwater intruding into the gap between the unit and the roof tile does not reach the base surface of the roof, so that the corrosion of the base surface of the roof can be prevented.

According to still another aspect of the present invention, there is provided a method for mounting a solar cell unit on a partly tile-covered oblique roof, the solar cell unit comprising a rectangular solar cell module, a module frame having two horizontal frame portions and first and second side frame portions, and a drain channel provided along the first side frame portion as described above, the method comprising the steps of: providing a rectangular installation region on the oblique roof, the rectangular installation region having two horizontal edges parallel to a roof ridge or an eave and two side edges respectively extending from opposite ends of one of the horizontal edges to opposite ends of the other horizontal edge; and mounting the unit in the installation region so that the second side frame portion of the unit is opposed to one of the side edges of the installation region to provide a gap between the second side frame portion and the one side edge; wherein the one side edge of the installation region is defined by a side edge of a roof tile; wherein the side edge of the roof tile opposed to the second side frame portion has an underlap portion projecting horizontally outward from a lower portion of the side edge; wherein the gap providing step comprises the step of providing the gap between the second side frame portion and the side edge of the roof tile so that the underlap portion of the roof tile is located below the gap.

In this method, the gap is defined between the second side frame portion of the solar cell unit and the side edge of the roof tile, and the underlap portion of the roof tile is located below the gap. Therefore, rainwater intruding into the gap between the unit and the roof tile is received by the underlap portion thereby to be drained. As a result, the rainwater intruding into the gap between the unit and the roof tile does not reach the base surface of the roof, so that the corrosion of the base surface of the roof can be prevented.

With reference to the attached drawings, the present invention will hereinafter be described in detail by way of an embodiment thereof.

Embodiment

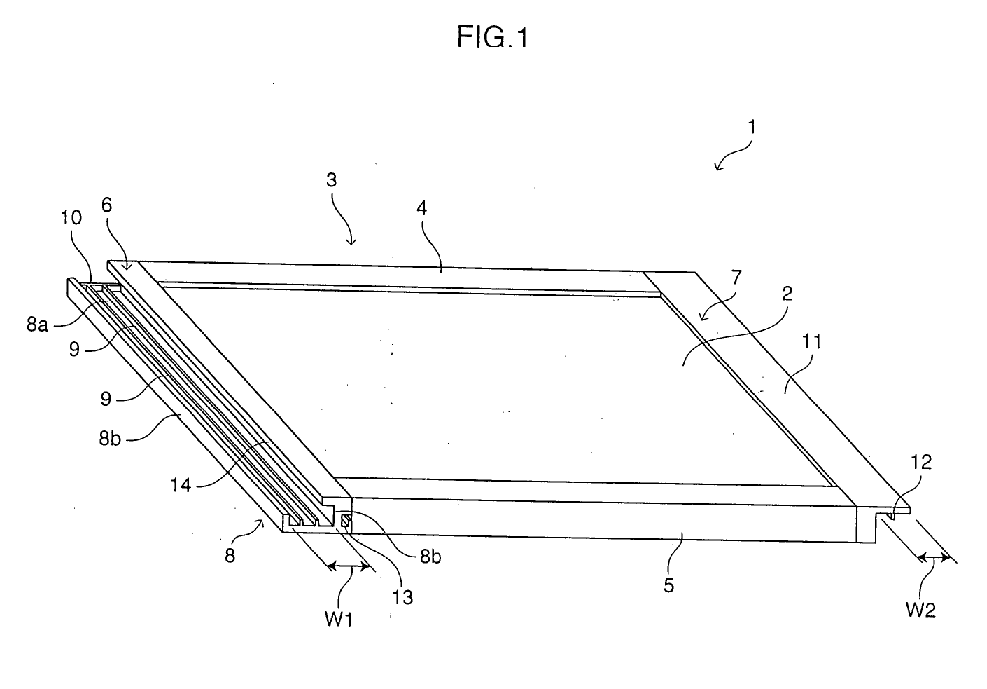

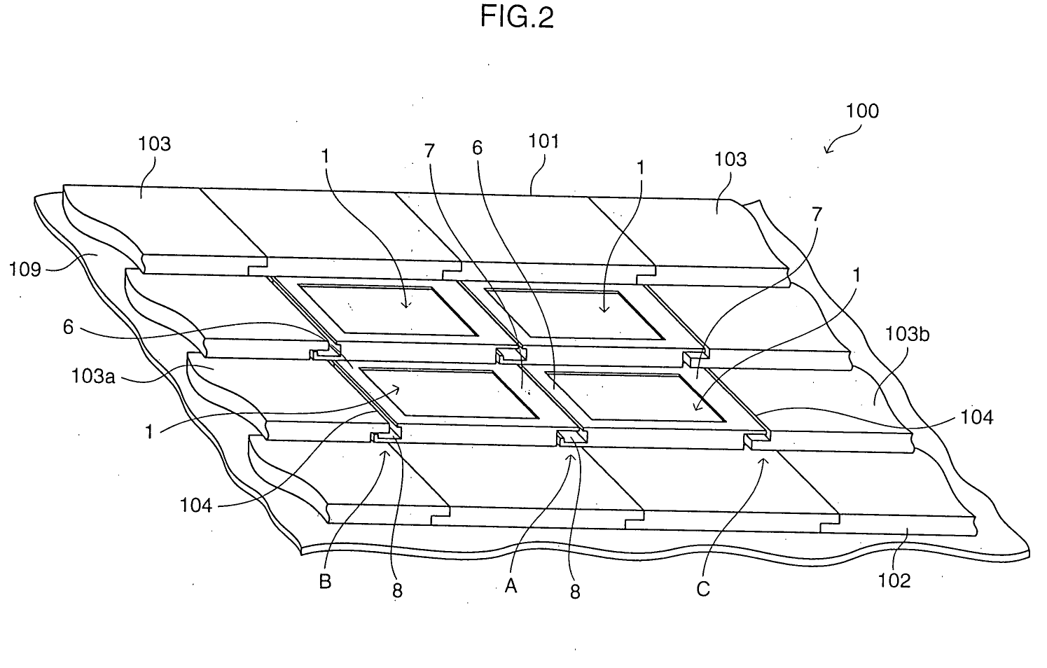

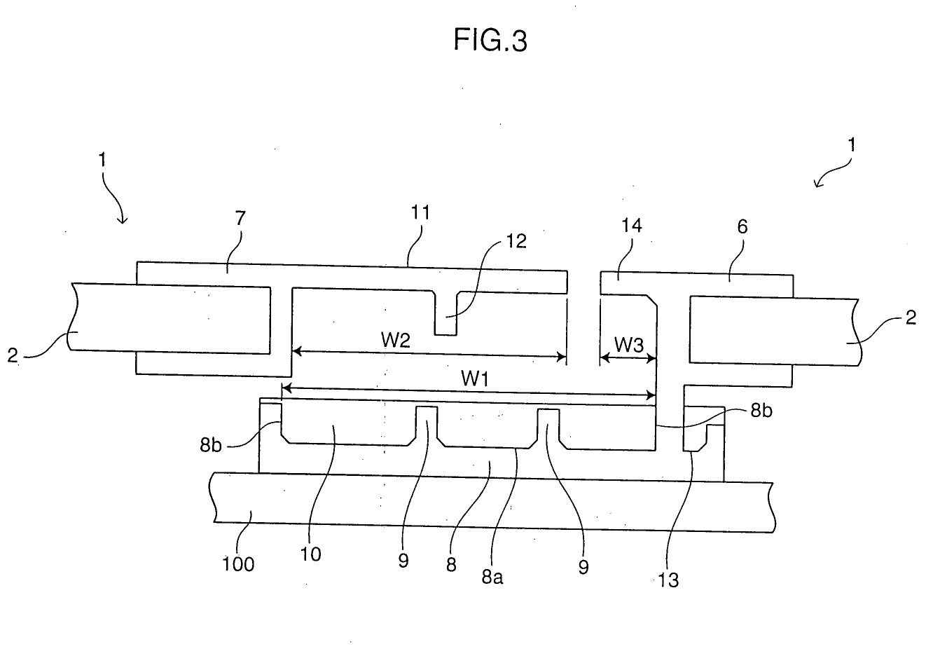

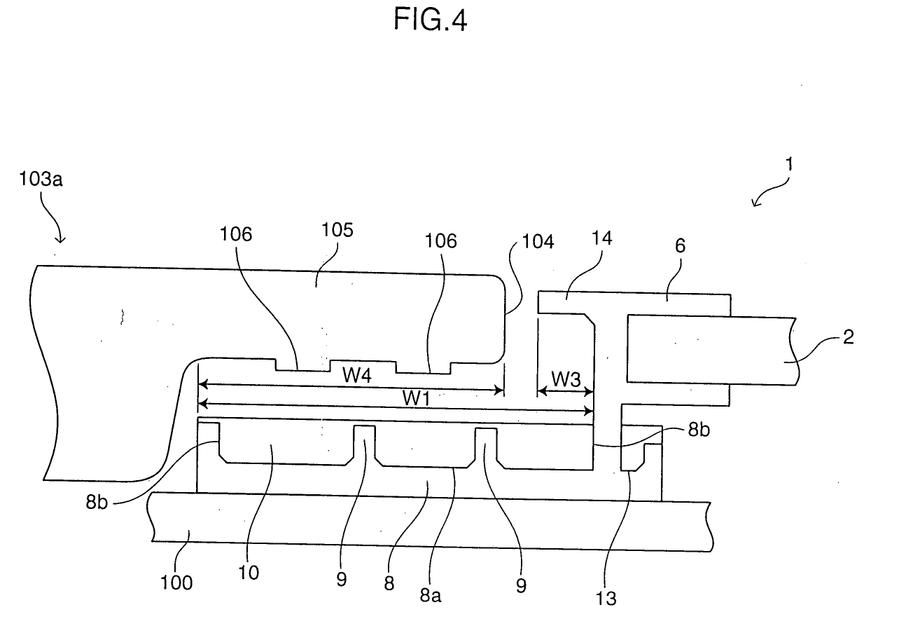

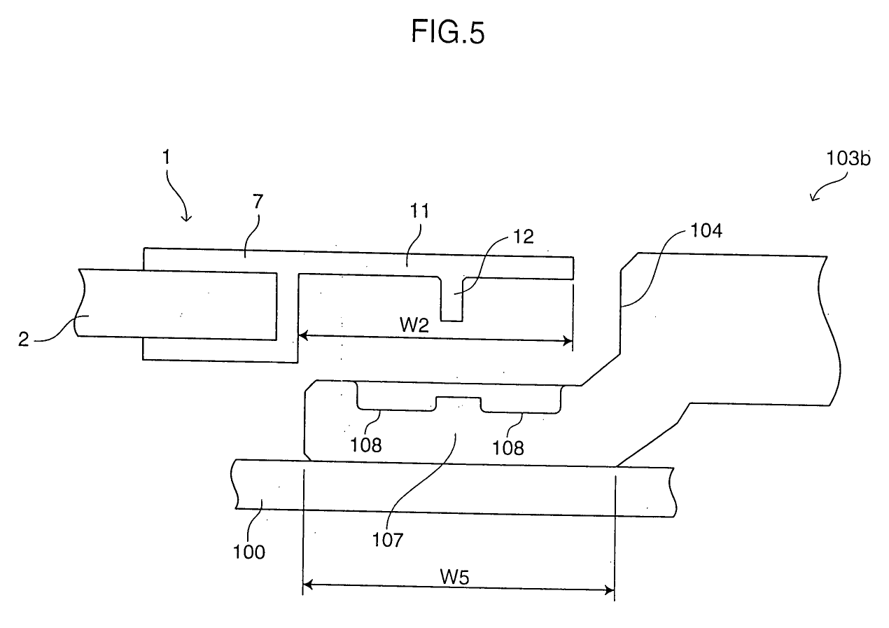

A solar cell unit according to the embodiment of the present invention will be described in detail with reference to FIGS. 1 to 5. FIG. 1 is a perspective view schematically illustrating the overall construction of a solar cell unit according to this embodiment. FIG. 2 is a perspective view schematically illustrating a plurality of solar cell units of FIG. 1 mounted on an installation region of an oblique roof. FIG. 3 is an explanatory diagram illustrating a portion A of FIG. 2 as seen parallel to a surface of the roof from the side of an eave. FIG. 4 is an explanatory diagram illustrating a portion B of FIG. 2 as seen parallel to the surface of the roof from the side of the eave. FIG. 5 is an explanatory diagram illustrating a portion C of FIG. 2 as seen parallel to the surface of the roof from the side of the eave.

As shown in FIGS. 1 and 2, the solar cell unit 1 according to this embodiment includes a solar cell module 2, a module frame 3 provided around the solar cell module 2 as supporting the solar cell module 2 for mounting the solar cell unit on the oblique roof 100, and a drain channel 8 provided along an edge of the module frame 3 outside the module frame 3. When a plurality of such solar cell units 1 are arranged on the oblique roof 100, the drain channels 8 of the respective solar cell units 1 receive rainwater intruding into gaps defined between the module frames and guide the rainwater toward the eave 102 of the oblique roof 100 for draining the rainwater.

The solar cell module 2 has a rectangular shape. The module frame 3 includes two horizontal frame portions 4 and 5 provided parallel to each other to be disposed on the side of a roof ridge 101 and on the side of the eave 102, respectively, when the solar cell unit 1 is mounted on the oblique roof 100, and a first side frame portion 6 and a second side frame portion 7 respectively extending from opposite ends of the horizontal frame portion 4 to opposite ends of the horizontal frame portion 5. The drain channel 8 is provided along the outer side of the first side frame portion 6.

As shown in FIG. 1, the drain channel 8 has ribs 9 projecting upward from the bottom thereof and extending longitudinally thereof. In this embodiment, two ribs 9 are provided thereby to be allowed to have a moderate height. If the height of the ribs 9 is too great, there is a possibility that, when the solar cell unit 1 is disposed adjacent a roof tile 103a as will be described later (see FIG. 4), the solar cell unit 1 cannot flexibly be installed on the roof with the ribs 9 in abutment against an overlap portion 105 of the roof tile 103a.

As shown in FIG. 1, the drain channel 8 has a barrier plate 10 which closes one end thereof. The drain channel 8 includes a channel bottom 8a and opposite side walls 8b. The second side frame portion 7 has a planar projection 11 projecting horizontally outward from the entire upper edge thereof. The projection 11 is located at a higher level than the side walls 8b of the drain channel 8. The drain channel 8 and the projection 11 each have a predetermined width. The width W1 of the drain channel 8 is greater than the width W2 of the projection 11.

As shown in FIG. 1, the projection 11 has a drip rib 12 projecting downward from a rear surface thereof and extending along the second side frame portion 7 for dripping rainwater flowing along the rear surface thereof. In this embodiment, the drip rib 12 is not necessarily required to have a great height, but has a moderate height. If the height of the drip rib 12 is too great, there is a possibility that, when the solar cell unit 1 is disposed adjacent a roof tile 103b as will be described later (see FIG. 5), the solar cell unit 1 cannot flexibly be installed on the roof with the drip rib 12 in abutment against an underlap portion 107 of the roof tile 103b.

As shown in FIG. 1, the first side frame portion 6 further has an auxiliary drain channel 13 projecting under the module 2 and extending along the inner side thereof. The first side frame portion 6 further has an auxiliary planar projection 14 projecting horizontally outward from the entire upper edge thereof.

The solar cell units 1 each having the aforesaid construction are installed on the oblique roof 100 as shown in FIG. 2.

In the case of the installation shown in FIG. 2, the solar cell units 1 are arranged parallel to the roof ridge 101 or the eave 102 on an installation region provided by removing some roof tiles 103 from the tile-covered oblique roof 100, so that the first side frame portion 6 of one of two laterally adjacent units 1, 1 and the second side frame portion 7 of the other unit 1 are disposed in opposed relation with a gap being defined therebetween and the drain channel 8 provided along the first side frame portion 6 of the one unit 1 is located below the gap. In this case, a water drain mechanism is provided in a portion A shown in FIG. 2 between the laterally adjacent solar cell units 1. The portion A of FIG. 2 is illustrated on greater scale in FIG. 3.

As shown in FIG. 3, the gap is defined between the first side frame portion 6 and the second side frame portion 7 of the adjacent solar cell units 1, 1 mounted on the oblique roof 100. Rainwater intruding into the gap between the first side frame portion 6 and the second side frame portion 7 of the adjacent solar cell units 1, 1 is received by the drain channel 8 provided along the first side frame portion 6 of the one solar cell unit 1, and guided toward the eave 102 of the oblique roof 100 (see FIG. 2) thereby to be drained.

Even a small amount of rainwater intruding into the gap properly flows through flow channels narrowly restricted by the ribs 9 projecting upward from the channel bottom 8a of the drain channel 8, and is drained at a proper flow rate through the drain channel 8. Thus, accumulation of dust in the drain channel 8 can be prevented.

As shown in FIG. 3, rainwater intruding into the rear side of the solar cell unit 1 for a certain reason is received by the auxiliary drain channel 13 provided on the inner side of the first side frame portion 6 as projecting under the solar cell module 2, and guided toward the eave 102 of the oblique roof 100 (see FIG. 2) thereby to be drained.

Where the rainwater flows back toward the roof ridge 101 (see FIG. 2) in the drain channel 8 due to a strong wind blowing from the side of the eave 102 (see FIG. 2), the rainwater is blocked by the barrier plate 10 closing the ridge-side end of the drain channel 8. Therefore, even if the ridge-side end of the drain channel 8 is located below another solar cell unit 1 disposed on the upper side (on the roof ridge side) as shown in FIG. 2, the rainwater is prevented from being drained from the ridge-side end of the drain channel 8 to wet the base surface 109 of the oblique roof 100.

As shown in FIG. 3, the planar projection 11 projecting horizontally outward from the entire upper edge of the second side frame portion 7 of the solar cell unit 1 and the planar auxiliary projection 14 projecting horizontally outward from the entire upper edge of the first side frame portion 6 of the solar cell unit 1 partly cover the drain channel 8 of the solar cell unit 1 thereby to prevent an unnecessarily great amount of rainwater from flowing into the drain channel 8. Here, the width W1 of the drain channel 8 is greater than the sum of the width W2 of the projection 11 and the width W3 of the auxiliary projection 14, so that the rainwater intruding into the gap between the adjacent solar cell units 1, 1 can assuredly be received by the drain channel 8 and guided toward the eave 102 (see FIG. 2) thereby to be drained.

Further, even if there is a dimensional difference between the size of the installation region provided by removing the roof tiles 103 from the tile-covered oblique roof 100 and the total size of the solar cell units 1 arranged on the roof, the dimensional difference can flexibly be accommodated for easy installation of the solar cell units by properly adjusting the width of the gap.

The drip rib 12 projecting downward from the rear surface of the projection 11 and extending along the second side frame portion 7 serves to block the rainwater flowing along the surface of the second side frame portion 7 to the rear side, and drip the rainwater into the drain channel 8. Thus, the rainwater is prevented from intruding into the rear side of the solar cell unit 1.

In the case of the installation shown in FIG. 2, the first side frame portion 6 of the solar cell unit 1 disposed adjacent the roof tile 103a located along one side edge of the installation region is opposed to a side edge 104 of the roof tile 103a, so that a gap is defined between the first side frame portion 6 and the side edge 104 of the roof tile 103a and the drain channel 8 provided along the first side frame portion 6 is located below the gap. In this case, a water drain mechanism is provided in a portion B shown in FIG. 2 between the solar cell unit 1 and the roof tile 103a disposed adjacent each other. The portion B of FIG. 2 is illustrated on greater scale in FIG. 4.

As shown in FIG. 4, the gap is defined between the side edge 104 of the roof tile 103a and the first side frame portion 6 of the solar cell unit 1 mounted adjacent the roof tile 103a on the oblique roof 100, and the drain channel 8 provided along the first side frame portion 6 is located below the gap. Therefore, rainwater intruding into the gap defined between the first side frame portion 6 and the side edge 104 of the roof tile 103a disposed adjacent to each other is received by the drain channel 8 provided along the first side frame portion 6 of the solar cell unit 1, and guided toward the eave 102 of the oblique roof 100 (see FIG. 2) thereby to be drained.

Here, the overlap portion 105 of the roof tile 103a and the auxiliary projection 14 of the first side frame portion 6 partly cover the drain channel 8 to prevent an unnecessarily great amount of rainwater from flowing into the drain channel 8 as in the drain channel 8 located between the adjacent solar cell units 1, 1. Since the width W1 of the drain channel 8 is greater than the sum of the width W3 of the auxiliary projection 14 and the width W4 of the overlap portion 105, the rainwater intruding into the gap defined between the solar cell unit 1 and the roof tile 103a disposed adjacent each other can assuredly be received by the drain channel 8 and guided toward the eave 102 (see FIG. 2) thereby to be drained. Further, even if there is a dimensional difference between the size of the installation region provided by removing the roof tiles from the tile-covered oblique roof 100 and the total size of the solar cell units 1 arranged on the roof, the dimensional difference can flexibly be accommodated for easy installation of the solar cell units by properly adjusting the width of the gap.

As shown in FIG. 4, the roof tile 103a has drip portions 106 provided on a rear surface of the overlap portion 105 thereof and having the same function as the drip rib 12 provided on the rear surface of the projection 11 of the solar cell unit 1. Thus, rainwater flowing from a front surface to the rear side of the roof tile 103a is blocked to be dripped into the drain channel 8 by the drip portions 106 thereby to be prevented from intruding into the rear side of the roof tile 103a.

In the case of the installation shown in FIG. 2, the second side frame portion 7 of the solar cell unit 1 disposed adjacent the roof tile 103b located along the other side edge of the installation region is opposed to a side edge 104 of the roof tile 103b, so that a gap is defined between the second side frame portion 7 and the side edge 104 of the roof tile 103b and an underlap portion 107 of the roof tile 103b is located below the gap. In this case, a water drain mechanism is provided in a portion C shown in FIG. 2 between the solar cell unit 1 and the roof tile 103b disposed adjacent each other. The portion C of FIG. 2 is illustrated on greater scale in FIG. 5.

As shown in FIG. 5, the gap is defined between the side edge 104 of the roof tile 103b and the second side frame portion 7 of the solar cell unit 1 mounted adjacent the roof tile 103b on the oblique roof 100, and the underlap portion 107 of the roof tile 103b is located below the gap. The underlap portion 107 has gutters 108, which have the same function as the drain channel 8 of the first side frame portion 6. Therefore, rainwater intruding into the gap defined between the second side frame portion 7 and the side edge 104 of the roof tile 103b disposed adjacent each other is received by the gutters 108 of the underlap portion 107 of the roof tile 103b and guided toward the eave 102 of the oblique roof 100 (see FIG. 2) thereby to be drained.

Here, the projection 11 of the second side frame portion 7 partly covers the underlap portion 107 to prevent an unnecessarily great amount of rainwater from flowing into the gutters 108 as in the drain channel 8 located between the adjacent solar cell units 1, 1. Since the width W5 of the underlap portion 107 is greater than the width W2 of the projection 11, the rainwater intruding into the gap defined between the solar cell unit 1 and the roof tile 103b disposed adjacent each other can assuredly be received by the gutters 108 of the underlap portion 107 and guided toward the eave 102 thereby to be drained. Further, even if there is a dimensional difference between the size of the installation region provided by removing the roof tiles 103 from the tile-covered oblique roof 100 and the total size of the solar cell units 1 arranged on the roof, the dimensional difference can flexibly be accommodated for easy installation of the solar cell units by properly adjusting the width of the gap.

As shown in FIG. 5, rainwater flowing from a front surface to the rear side of the second side frame portion 7 is blocked to be dripped onto the underlap portion 107 by the drip rib 12 provided on the rear surface of the projection 11 thereby to be prevented from intruding into the rear side of the solar cell unit 1.

According to the present invention, the solar cell units each include the drain channel provided along the edge of the module frame outside the module frame. Therefore, when the solar cell units are mounted on the oblique roof, the rainwater intruding into the gaps defined between the module frames of the respective units can be received by the drain channels of the units and guided toward the eave of the oblique roof thereby to be drained. This makes it possible to prevent the corrosion of the base surface of the roof.

Further, even if the gaps are provided between the solar cell units, the rainwater does not reach the base surface of the roof. Therefore, the dimensional difference between the size of the installation region of the oblique roof and the total size of the solar cell units arranged on the roof can flexibly be accommodated by positively providing the gaps between the solar cell units and properly adjusting the width of the gaps when the solar cell units are mounted on the roof.

What is claimed is:

1. A solar cell unit comprising:
a solar cell module;
a module frame provided around the solar cell module as supporting the solar cell module for mounting the solar cell unit on an oblique roof; and
a drain channel provided along an edge of the module frame outside the module frame.

2. A solar cell unit as set forth in claim 1,
wherein the solar cell module has a rectangular shape;
the module frame includes two horizontal frame portions provided parallel to each other to be disposed on a roof ridge side and on an eave side, respectively, when the solar cell unit is mounted on the oblique roof, and a first side frame portion and a second side frame portion respectively extending from opposite ends of one of the horizontal frame portions to opposite ends of the other horizontal frame portion; and
the drain channel is provided along an outer side of the first side frame portion.

3. A solar cell unit as set forth in claim 1, wherein the drain channel has a rib projecting upward from a bottom of the drain channel and extending longitudinally of the drain channel.

4. A solar cell unit as set forth in claim 2, wherein the drain channel has a barrier plate which closes one end of the drain channel located on the roof ridge side.

5. A solar cell unit as set forth in claim 2,
wherein the drain channel includes a channel bottom and opposite side walls;
the second side frame portion has a planar projection projecting horizontally outward from an entire upper edge of the second side frame portion; and
the projection is located at a higher level than the side walls of the drain channel.

6. A solar cell unit as set forth in claim 5,
wherein the drain channel and the projection each have a predetermined width; and
the width of the drain channel is greater than the width of the projection.

7. A solar cell unit as set forth in claim 5, wherein the projection has a rib projecting downward from a rear surface of the projection and extending along the second side frame portion for dripping rainwater flowing along the rear surface of the projection.

8. A solar cell unit as set forth in claim 5, wherein the first side frame portion further has an auxiliary drain channel projecting under the module and extending along an inner side of the first side frame portion.

9. A solar cell unit as set forth in claim 5, wherein the first side frame portion further has a planar auxiliary projection projecting horizontally outward from an entire upper edge of the first side frame portion.

10. A method for mounting a plurality of solar cell units on an oblique roof, the solar cell units each comprising:
a rectangular solar cell module;
a module frame provided around the solar cell module as supporting the solar cell module for mounting the solar cell unit on an oblique roof, the module frame including two horizontal frame portions provided parallel to each other to be disposed on a roof ridge side and on an eave side, respectively, when the solar cell unit is mounted on the oblique roof, and a first side frame portion and a second side frame portion respectively extending from opposite ends of one of the horizontal frame portions to opposite ends of the other horizontal frame portion; and
a drain channel provided along an outer side of the first side frame portion,
the method comprising the step of mounting the solar cell units parallel to a roof ridge or an eave on the oblique roof so that the first side frame portion of one of two adjacent solar cell units and the second frame portion of the other solar cell unit are opposed to each other with a gap being defined therebetween and the drain channel provided along the first side frame portion of the one unit is located below the gap.

11. A method for mounting a solar cell unit on a partly tile-covered oblique roof, the solar cell unit comprising:
a rectangular solar cell module;
a module frame provided around the solar cell module as supporting the solar cell module for mounting the solar cell unit on an oblique roof, the module frame including two horizontal frame portions provided parallel to each other to be disposed on a roof ridge side and on an eave side, respectively, when the solar cell unit is mounted on the oblique roof, and a first side frame portion and a second side frame portion respectively extending from opposite ends of one of the horizontal frame portions to opposite ends of the other horizontal frame portion; and
a drain channel provided along an outer side of the first side frame portion,
the method comprising the steps of:
providing a rectangular installation region on the oblique roof, the rectangular installation region having two horizontal edges parallel to a roof ridge or an eave and two side edges respectively extending from opposite ends of one of the horizontal edges to opposite ends of the other horizontal edge; and
mounting the unit on the installation region so that the first side frame portion of the unit is opposed to one of the side edges of the installation region to provide a gap between the first side frame portion and the one side edge and the drain channel provided along the first side frame portion is located below the gap;
wherein the side edges of the installation region are each defined by a side edge of a roof tile; and
the gap providing step comprises the step of providing the gap between the first side frame portion and the side edge of the roof tile.

12. A method for mounting a solar cell unit on a partly tile-covered oblique roof, the solar cell unit comprising:
a rectangular solar cell module;
a module frame provided around the solar cell module as supporting the solar cell module for mounting the solar cell unit on an oblique roof, the module frame including two horizontal frame portions provided parallel to each other to be disposed on a roof ridge side and on an eave side, respectively, when the solar cell unit is mounted on the oblique roof, and a first side frame portion and a second side frame portion respectively extending from opposite ends of one of the horizontal frame portions to opposite ends of the other horizontal frame portion; and
a drain channel provided along an outer side of the first side frame portion,
the method comprising the steps of:
providing a rectangular installation region on the oblique roof, the rectangular installation region having two horizontal edges parallel to a roof ridge or an eave and two side edges respectively extending from opposite ends of one of the horizontal edges to opposite ends of the other horizontal edge; and
mounting the unit on the installation region so that the second side frame portion of the unit is opposed to one of the side edges of the installation region to provide a gap between the second side frame portion and the one side edge;
wherein the one side edge of the installation region is defined by a side edge of a roof tile;
the side edge of the roof tile opposed to the second side frame portion has an underlap portion projecting horizontally outward from a lower portion of the side edge; and
the gap providing step comprises the step of providing the gap between the second side frame portion and the side edge of the roof tile so that the underlap portion of the roof tile is located below the gap.
